(19) United States
(12) Patent Application Publication
(10) Pub. No.: US 2024/0047635 A1
(43) Pub. Date: Feb. 8, 2024

(54) LIGHT-EMITTING DEVICE, BACKPLATE ASSEMBLY AND DISPLAY PANEL

(71) Applicant: Xiamen Extremely PQ Display Technology Co., Ltd., Xiamen (CN)

(72) Inventor: GANG MA, Xiamen (CN)

(21) Appl. No.: 18/489,880

(22) Filed: Oct. 19, 2023

Related U.S. Application Data
(63) Continuation of application No. PCT/CN2023/104386, filed on Jun. 30, 2023.

(30) Foreign Application Priority Data
Jul. 22, 2022 (CN) 2022108681072

(51) Int. Cl. H01L 33/62; H01L 25/16; H01L 23/00

(52) U.S. Cl. CPC H01L 33/62; H01L 25/167; H01L 24/32; H01L 24/29; H01L 24/16; H01L 24/13; H01L 24/05; H01L 2224/05073; H01L 2224/05573; H01L 2224/13111; H01L 2224/13109; H01L 2224/29111; H01L 2224/29109; H01L 2924/014; H01L 2224/16145; H01L 2224/32145; H01L 2924/12041; H01L 2924/1426; H01L 24/11; H01L 24/27; H01L 2224/2745; H01L 2224/1145; H01L 24/81; H01L 24/83; H01L 2224/81815; H01L 2224/83815

(57) ABSTRACT

A light-emitting device used for a display panel includes: a light-emitting element and a solder gradient layer, the light-emitting element includes a light-emitting epitaxial layer and a pad layer formed on the light-emitting epitaxial layer, the solder gradient layer is disposed on the pad layer, and a melting point of the solder gradient layer gradually decreases in a direction facing away from the pad layer. In a process of soldering the light-emitting device to a backplate, because there are multiple melting point regions or metal layers with different melting points in the solder gradient layer, a temperature of primary soldering is controlled to be higher than that of repair soldering in the processes of the primary soldering and the repair soldering, which can avoid an influence of the repair soldering on a solder joint formed during the primary soldering, and effectively control a yield of soldering.

### TECHNICAL FIELD

The disclosure relates to the field of semiconductor device packaging technologies, and particularly to a light-emitting device, a backplate assembly and a display panel.

### BACKGROUND

When packaging a semiconductor device, a chip needs to be disposed on a backplate and connected with the backplate in a conductive way. When conducting the conductive connection between the chip and the backplate, it is generally necessary to deposit a solder on the chip or the backplate, and after the specific solder is melted, a metallurgical bonding point is formed to solder the chip and the backplate.

In a related art, a solder with a fixed melting point is usually deposited on a chip or a backplate, and a suitable range of a soldering temperature is generally narrow due to the fixed melting point of the solder. However, chips and other components may be used in different products of different customers, for different applications, due to the temperature resistance or other characteristics of other components in customers' products, expected soldering temperatures of the chips and other components are different, thus improving the usability of the chips and other components is very important to improve the user experience, and how to improve the applicability of the chips and other components has become a technical problem that needs to be solved urgently by those skilled in the art.

In addition, in a micro-light emitting diode (micro-LED) display device, a soldering temperature is generally fixed when a chip is soldered to a backplate, the chip generally needs to be soldered twice, after the primary soldering, the chip needs to be detected and then the secondary repair soldering is performed on the chip. However, the secondary repair soldering will have an impact on the already formed solder joints owning to the fixed soldering temperature, for example, the formed solder joints need to be melted, thus affecting the soldering reliability.

### SUMMARY

### Technical Problem

Based on the above defects, a purpose of the disclosure is to provide a light-emitting device, a backplate assembly and a display panel, so as to improve an application range of components such as chips and improve the reliability of soldering.

### Technical Solutions

In order to achieve the above purpose and other related purposes, the disclosure provides a light-emitting device, including:

a light-emitting element, including: a light-emitting epitaxial layer and a pad layer formed on the light-emitting epitaxial layer; and

a solder gradient layer, disposed on the pad layer of the light-emitting element; and a melting point of the solder gradient layer gradually decreases in a direction facing away from the pad layer.

In an embodiment, the solder gradient layer is a single-layer structure including at least two metal materials, and a content of each of the at least two metal materials in the single-layer structure is different in the direction facing away from the pad layer.

In an embodiment, the solder gradient layer includes indium (In) and tin (Xi), and a content of the indium in the solder gradient layer gradually increases in the direction facing away from the solder pad layer.

In an embodiment, the solder gradient layer includes a first melting point region, a second melting point region and a third melting point region sequentially arranged in the direction facing away from the pad layer; and a melting point of the first melting point region is in a range of 180° C. to 230° C., a melting point of the second melting point region is in a range of 120° C. to 180° C., and a melting point of the third melting point region is in a range of 100° C. to 120° C.

In an embodiment, a content of the indium in the first melting point region is in a range of 0 to 25%, a content of the indium in the second melting point region is in a range of 25% to 60%, and a content of the indium in the third melting point region is in a range of 60% to 70%.

In an embodiment, the light-emitting element further includes an electrode structure disposed between the light-emitting epitaxial layer and the pad layer; a distance between a surface of the solder gradient layer facing away from the light-emitting element and a surface of the electrode structure facing away from the solder layer is defined as a thickness of the solder gradient layer; and a ratio of the thickness of the solder gradient layer to an area of orthogonal projection of the solder gradient layer on the light-emitting element is in a range of 0.001 to 0.1.

In an embodiment, the light-emitting element further includes an electrode structure disposed between the light-emitting epitaxial layer and the pad layer; a distance between a surface of the solder gradient layer facing away from the light-emitting element and a surface of the electrode structure facing away from the solder layer is defined as a thickness of the solder gradient layer; and a ratio of the thickness of the solder gradient layer to a maximum width of orthogonal projection of the solder gradient layer on the light-emitting element is in a range of 0.01 to 0.3.

In an embodiment, the light-emitting element further includes an adhesive layer disposed between the light-emitting epitaxial layer and the pad layer, and an area of orthogonal projection of the adhesive layer on the light-emitting epitaxial layer is 1.15 to 2.5 times of an area of orthographic projection of the solder gradient layer on the light-emitting epitaxial layer.

In an embodiment, the light-emitting element further includes an adhesive layer disposed between the light-emitting epitaxial layer and the pad layer, and an electrode structure disposed between the adhesive layer and the light-emitting epitaxial layer; and an area of orthographic projection of the adhesive layer on the light-emitting epitaxial layer is 1.15 to 2.5 times of an area of orthographic projection of the electrode structure on the light-emitting epitaxial layer.

The disclosure further provides a backplate assembly, including:
a backplate, including a pad for soldering a light-emitting element; and
a solder gradient layer, disposed on the pad of the backplate; and a melting point of the solder gradient layer gradually decreases in a direction facing away from the pad.

In an embodiment, the solder gradient layer is a single-layer structure including at least two metal materials, and a content of each of the at least two metal materials in the single-layer structure is different in the direction facing away from the pad.

In an embodiment, the solder gradient layer includes indium and tin, and a content of the indium in the solder gradient layer gradually increases in the direction facing away from the pad.

In an embodiment, the solder gradient layer includes a first melting point region, a second melting point region and a third melting point region sequentially arranged in the direction facing away from the pad; and a melting point of the first melting point region is in a range of 180° C. to 230° C., a melting point of the second melting point region is in a range of 120° C. to 180° C., and a melting point of the third melting point region is in a range of 100° C. to 120° C.

In an embodiment, a content of the indium in the first melting point region is in a range of 0 to 25%, a content of the indium in the second melting point region is in a range of 25% to 60%, and a content of the indium in the third melting point region is in a range of 60% to 70%.

In an embodiment, the backplate further includes a connecting electrode disposed on a side of the pad facing away from the solder gradient layer, and a distance between a surface of the solder gradient layer facing away from the pad and a surface of the connecting electrode facing away from the pad is defined as a thickness of the solder gradient layer; and a ratio of the thickness of the solder gradient layer to an area of orthogonal projection of the solder gradient layer on the backplate is in a range of 0.001 to 0.1.

In an embodiment, the backplate further includes a connecting electrode disposed on a side of the pad facing away from the solder gradient layer; a distance between a surface of the solder gradient layer facing away from the pad and a surface of the connecting electrode facing away from the pad is defined as a thickness of the solder gradient layer; and a ratio of the thickness of the solder gradient layer to a maximum width of orthogonal projection of the solder gradient layer on the backplate is in a range of 0.01 to 0.3.

In an embodiment, the backplate further includes a substrate, the pad is disposed on a surface of the substrate, and the backplate further includes an adhesive layer disposed between the pad and the substrate; and an area of orthographic projection of the adhesive layer on the substrate is 1.15 to 2.5 times of an area of orthographic projection of the solder gradient layer on the substrate.

In an embodiment, the backplate further includes a substrate, the substrate is provided with a connecting electrode thereon, and the pad is disposed on the connecting electrode, the backplate further includes an adhesive layer disposed between the pad and the connecting electrode; and an area of orthographic projection of the adhesive layer on the substrate is 1.15 to 2.5 times of an area of orthographic projection of the electrode on the substrate.

The disclosure further provides a display panel, including:
a backplate; and
a light-emitting device, fixed on the backplate; the light-emitting device is the light-emitting device as described above, and the light-emitting device is soldered on the backplate through the solder gradient layer on the pad layer.

The disclosure further provides a display panel, including:
the backplate assembly as described above; and
a light-emitting element, soldered on the backplate assembly through the solder gradient layer.

### Beneficial Effects

Compared with the related art, the light-emitting device, the backplate assembly and the display panel provided by the disclosure at least have the following beneficial effects.

In the light-emitting device of the disclosure, the solder gradient layer is disposed on the pad layer, the melting point of the solder gradient layer gradually decreases in the direction facing away from the pad layer. In a process of soldering the light-emitting device to the backplate, because the solder gradient layer includes multiple melting point regions or metal layers with different melting points, a temperature of primary soldering is controlled to be higher than that of repair soldering in the processes of the primary soldering and the repair soldering, which can avoid an influence of the repair soldering on solder joints formed during the primary soldering and effectively control a yield of soldering.

In the backplate assembly of the disclosure, the solder gradient layer is disposed on the pad of the backplate, and the melting point of the solder gradient layer gradually decreases in the direction facing away from the pad. In a process of soldering the light-emitting element to the backplate assembly, because the solder gradient layer includes multiple melting point regions or metal layers with different melting points, a solder with a relatively low melting point facing away from the backplate is melted at a lower soldering temperature, and most of the solder with a relatively high melting point close to the backplate is not melted. The light-emitting element is detected, when a defective light-emitting element is found, a chip after the primary soldering is easier to remove.

In addition, the light-emitting device and the backplate assembly in the disclosure can also be applied to products with different soldering temperatures, and have wider applicability. The soldering method and the display panel described in the disclosure include the light-emitting device or the backplate assembly, and can also achieve the above technical effects.

### BRIEF DESCRIPTION OF DRAWINGS

FIG. 1A illustrates a schematic structural view of a light-emitting device according to an example of an embodiment 1 of the disclosure.

FIG. 1B illustrates a schematic structural view of a light-emitting device according to another example of the embodiment 1 of the disclosure.

FIG. 2A illustrates a schematic structural view of a light-emitting device according to further another example of the embodiment 1 of the disclosure.

FIG. 2B illustrates a schematic structural view of a light-emitting device according to still another example of the embodiment 1 of the disclosure.

FIG. 2C illustrates a schematic structural view of a light-emitting device according to even another example of the embodiment 1 of the disclosure.

FIG. 2D illustrates a schematic structural view of a light-emitting device according to still further another example of the embodiment 1 of the disclosure.

FIG. 2E illustrates a schematic structural view of a light-emitting device according to even further another example of the embodiment 1 of the disclosure.

FIG. 2F illustrates a schematic structural view of a light-emitting device according to still even further another example of the embodiment 1 of the disclosure.

FIG. 3A illustrates a schematic structural view of a backplate assembly according to an example of an embodiment 2 of the disclosure.

FIG. 3B illustrates a schematic structural view of a backplate assembly according to another example of the embodiment 2 of the disclosure.

FIG. 4A illustrates a schematic structural view of a backplate assembly according to further another example of the embodiment 2 of the disclosure.

FIG. 4B illustrates a schematic structural view of a backplate assembly according to still another example of the embodiment 2 of the disclosure.

FIG. 4C illustrates a schematic structural view of a backplate assembly according to even another example of the embodiment 2 of the disclosure.

FIG. 4D illustrates a schematic structural view of a backplate assembly according to still further another example of the embodiment 2 of the disclosure.

FIG. 5 illustrates a schematic structural view of transferring the light-emitting device according to the embodiment 1 of the disclosure to a top of a backplate.

FIG. 6 illustrates a schematic structural view of soldering the light-emitting device according to the embodiment 1 of the disclosure to a backplate.

FIG. 7 illustrates a schematic structural view of transferring a light-emitting element to a top of the backplate assembly according to the embodiment 2 of the disclosure.

FIG. 8 illustrates a schematic structural view of soldering a light-emitting element to the backplate assembly according to the embodiment 2 of the disclosure.

FIG. 9 illustrates a schematic structural view of a display panel according to an embodiment 3 of the disclosure.

FIG. 10 illustrates a schematic structural view of a display panel according to an embodiment 4 of the disclosure.

Description of reference numerals:

| | | | |
|---|---|---|---|
| 100 | solder gradient layer | 201 | first adhesive layer |
| 101 | first metal layer | 202 | pad layer |
| 102 | second metal layer | 203 | light-emitting epitaxial layer |
| 103 | third metal layer | 204 | electrode structure |
| 110 | first melting point region | 3 | backplate assembly |
| 120 | second melting point region | 300 | backplate |
| 130 | third melting point region | 301 | second adhesive layer |
| 2 | lighting-emitting device | 302 | primary soldering pad |
| 20 | lighting-emitting element | 303 | substrate |
| 200 | LED chip substrate | 304 | connecting electrode |

### DETAILED DESCRIPTION OF EMBODIMENTS

The following are specific embodiments to illustrate implementation ways of the disclosure. Those skilled in the art can easily understand the other advantages and effects of the disclosure from the content disclosed in the specification. The disclosure can also be implemented or applied through different specific implementation ways, and the details in the specification can also be modified or changed based on different perspectives and applications without departing from the spirit of the disclosure. It should be noted that, without conflict, the following embodiments and the features in the embodiments can be combined with each other.

It should be noted that the drawings provided in the embodiments of the disclosure only illustrate the basic concept of the disclosure in a schematic manner. Although the drawings only show the components related to the disclosure and are not drawn based on the actual numbers, shapes, and sizes of the components during implementation, the shape, quantity, and proportion of each component can be arbitrarily changed during the actual implementation, and the component layout may also be more complex. The structure, proportion, size, etc. shown in the accompanying drawings of the specification are only intended to complement the content disclosed in the specification for those skilled in the art to understand and read, and are not intended to limit the implementation of the disclosure. Therefore, they do not have any technical substantive significance. Any modifications to the structure, changes in the proportion relationship, or adjustments in the size do not affect the effectiveness and purpose that the disclosure can achieve, all of them should still fall within the scope of the technical content disclosed in the disclosure.

Based on the problem existing in the background technology and the related art, the disclosure provides a light-emitting device, a backplate assembly, a display panel and a soldering method for the light-emitting device. The light-emitting device or the backplate assembly is provided with a solder gradient layer with multiple gradient melting points, so as to set different soldering temperatures for different soldering processes, and improve the repairability of light-emitting diode (LED) chips.

### Embodiment 1

The embodiment provides a light-emitting device 2 for a display panel. The light-emitting device 2 includes a light-emitting element 20 and a solder gradient layer 100 disposed on the light-emitting element 20. The light-emitting element 20 includes a light-emitting epitaxial layer 203 and a pad layer 202 formed on the light-emitting epitaxial layer 203. The solder gradient layer 100 is disposed on the pad layer 202 of the light-emitting element 20, and a melting point of the solder gradient layer 100 gradually decreases in a direction facing away from the pad layer 202.

The formation of the pad layer 202 on the light-emitting epitaxial layer 203 can be understood as being formed on a side of the light-emitting epitaxial layer 203, but the embodiment is not limited to the pad layer 202 being directly disposed on a surface of the light-emitting epitaxial layer 203, and other necessary structural layers can be disposed between the pad layer 202 and the light-emitting epitaxial layer 203.

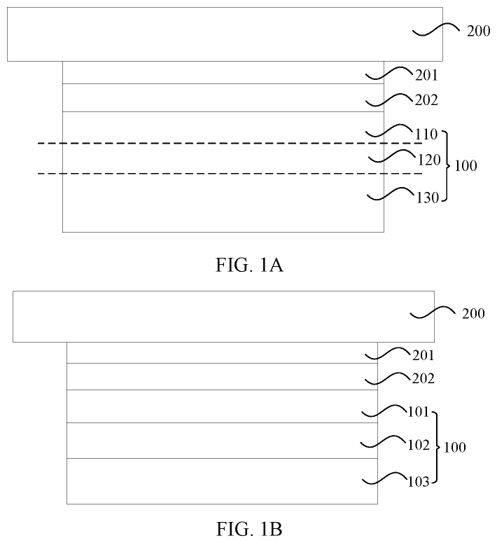

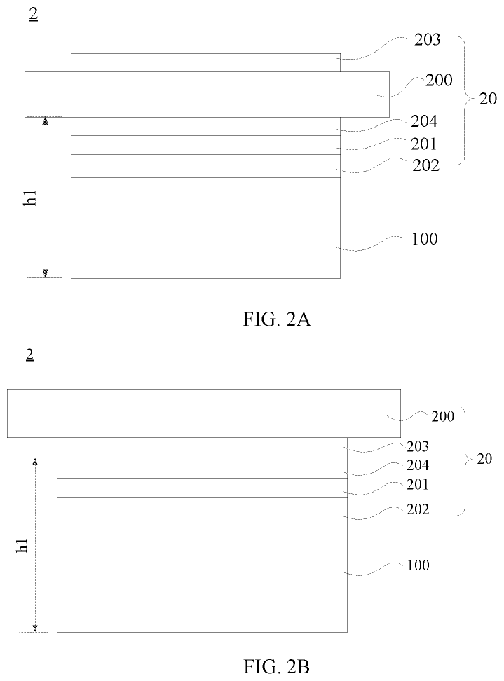

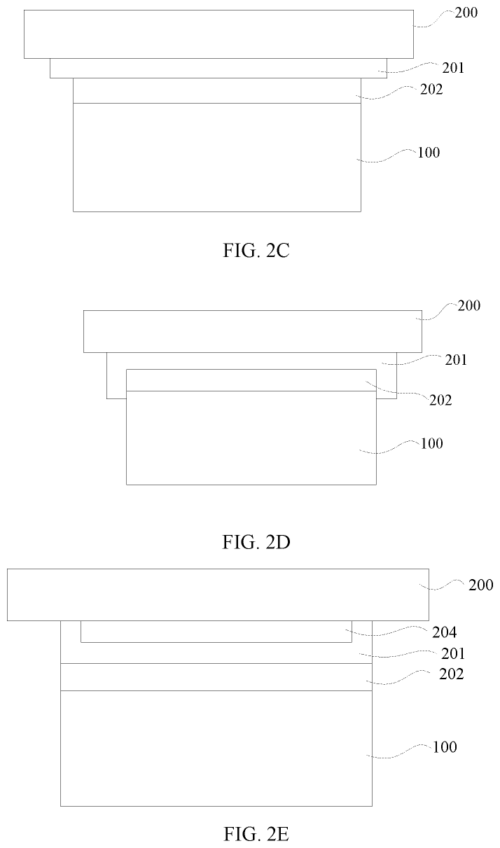

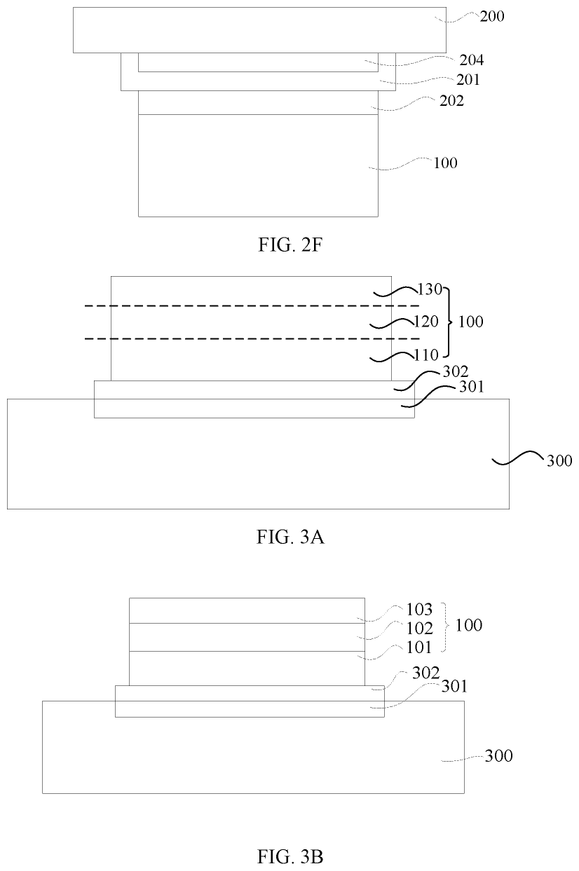

For example, in the light-emitting device 2, the light-emitting element 20 can be a LED chip. It should be noted that the light-emitting device 2 including the light-emitting element 20 and the solder gradient layer 100 can be regarded as an improved LED chip. For the convenience of explanation, a LED chip described in the embodiment is the light-emitting element 20 unless otherwise specified in the embodiment. Optionally, referring to FIG. 1A, the LED chip (i.e., the light-emitting element 20) includes a LED chip substrate 200 and a light-emitting epitaxial layer 203 formed on a surface of the LED chip substrate 200 (please refer to FIG. 2A or 2B). Optionally, the light-emitting epitaxial layer 203 includes a first semiconductor layer, an active layer and a second semiconductor layer with opposite conductivity type to the first semiconductor layer, which are sequentially formed on the surface of the LED chip substrate 200, and the active layer is a light-emitting layer of the light-emitting element. The first semiconductor layer may be an N-type semiconductor layer and the second semiconductor layer may be a P-type semiconductor layer. Of course, it is possible that the first semiconductor layer is a P-type semiconductor layer and the second semiconductor layer is an N-type semiconductor layer. Alternatively, the first semiconductor layer may be an N-type gallium nitride (GaN) layer, the active layer may be a quantum well layer, and the second semiconductor layer may be a P-type GaN layer. The light emitting element 20 can be a vertical LED chip or a flip-chip LED chip.

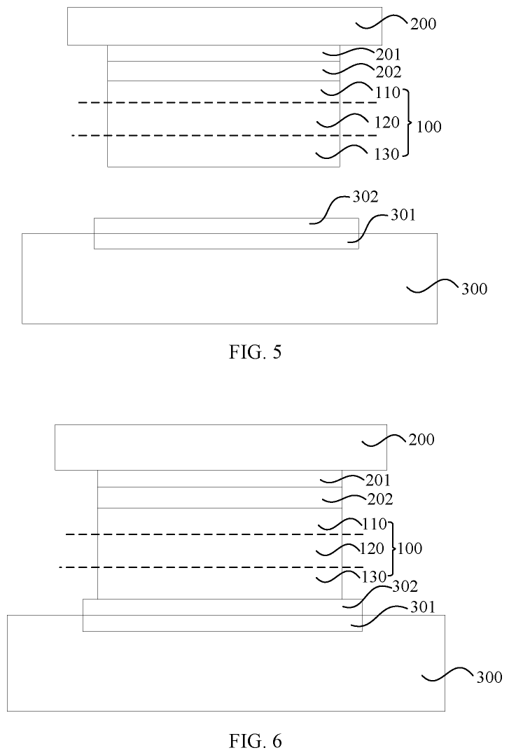

In the embodiment, referring to FIG. 2A, an electrode structure 204 is formed on another surface (a side facing away from the light-emitting epitaxial layer 203) of the LED chip substrate 200 (please refer to FIG. 2A). Or referring to FIG. 2B, in some embodiments, the electrode structure 204 may be disposed on a same side of the LED chip substrate 200 as the light-emitting epitaxial layer 203, that is, the electrode structure 204 is disposed on a side of the light-emitting epitaxial layer 203 facing away from the LED chip substrate 200. The pad layer 202 is formed on a surface of the electrode structure 204. It can be understood that the light-emitting element 20 further includes the electrode structure 204 disposed between the light-emitting epitaxial layer 203 and the pad layer 202, the electrode structure 204 is an N electrode (i.e., negative electrode) or a P electrode (i.e., positive electrode) of the LED chip, the N electrode is connected with the N-type semiconductor layer of the light-emitting epitaxial layer 203, and the P electrode is connected with the P-type semiconductor layer of the light-emitting epitaxial layer 203. It can be understood that when the light-emitting element 20 is the flip-chip LED chip, there are usually two electrode structures 204 (not shown in the figure) on the same side of the LED chip substrate 200, respectively corresponding to the N electrode and the P electrode. A surface of each electrode structure 204 is formed with the pad layer 202, referring to FIG. 5, the pad layer 202 is used to solder the LED chip (the light-emitting element 20) to a backplate 300. Optionally, an adhesive layer is formed between the electrode structure 204 on the surface of the LED chip substrate 200 and the pad layer 202. In the embodiment, the adhesive layer in the light emitting device 2 is also referred as a first adhesive layer 201, which is used to fix the pad layer 202 and the electrode structure 204.

Referring to FIG. 1A or 1B, the solder gradient layer 100 is formed on the pad layer 202 of the light-emitting element 20, and the melting point of the solder gradient layer 100 gradually decreases in the direction facing away from the pad layer 202. Referring to an orientation shown in FIGS. 1A and 1B, the solder gradient layer 100 is disposed below the pad layer 202, and the melting point of the solder gradient layer 100 gradually decreases in a direction from top to down.

In an embodiment, referring to FIG. 1A, the solder gradient layer 100 includes a single-layer structure formed of at least two metal materials, and a content of each of the at least two metal materials in the single-layer structure is different in the direction facing away from the pad layer 202. Specifically, in an embodiment, the solder gradient layer 100 includes tin (Xi) and indium (In). The solder gradient layer 100 includes a first melting point region 110, a second melting point region 120 and a third melting point region 130 sequentially arranged in the direction facing away from the pad layer 202. A melting point of the first melting point region 110 is in a range of 180° C. to 230° C., a melting point of the second melting point region 120 is in a range of 120° C. to 180° C. and a melting point of the third melting point region 130 is in a range of 100° C. to 120° C. In some embodiments, an indium content of the first melting point region 110 is in a range of 0 to 25%, an indium content of the second melting point region 120 is in a range of 25% to 60%, and an indium content of the third melting point region 130 is in a range of 60% to 70%. The solder gradient layer 100 can be gradually formed on the pad layer of the light emitting element 20 by multi-source evaporation. For example, in an evaporation process, a ratio of tin to indium is successively controlled as follows: Sn:In=8:1, Sn:In=7:1, Sn:In=6:1, Sn:In=5:1, Sn:In=4:1, Sn:In=3:1 and Sn:In=2:1. After evaporating the same thickness under the same proportion of indium and tin, the proportion of indium and tin is adjusted once until the solder gradient layer 100 is formed.

In another embodiment, referring to FIG. 1B, the solder gradient layer 100 includes a multi-layer structure, and the multi-layer structure includes multiple metal layers which are sequentially stacked, and the multiple metal layers have different melting points. Each of the multiple metal layers can be formed by mixing at least two metals or a single metal, and the metals contained in each metal layer can be the same or different. It should be noted that in the embodiment, as long as melting points of the metal layers are different and the melting points of the metal layers gradually decrease in the direction facing away from the pad layer 202, the material composition of each metal layer is not limited. Specifically, referring to FIG. 1B, the solder gradient layer 100 includes a first metal layer 101, a second metal layer 102 and a third metal layer 103 sequentially arranged in the direction facing away from the pad layer 202, and each metal layer is formed by multi-source evaporation. A melting point of the first metal layer 101 is in a range of 180° C. to 230° C., a melting point of the second metal layer 102 is in a range of 120° C. to 180° C., and a melting point of the third metal layer 103 is in a range of 100° C. to 120° C. The first metal layer 101 can be made of tin, the second metal layer 102 can be made of indium, and the third metal layer 103 can be made of indium and tin.

In some embodiments, referring to FIG. 2A or FIG. 2B, a distance h1 between a surface of the solder gradient layer 100 facing away from the light-emitting element 20 and a surface of the electrode structure 204 facing away from the solder layer 202 is defined as a thickness of the solder gradient layer 100. An area of orthogonal projection of the solder gradient layer 100 on the light-emitting element 20 is denoted as S1, and a ratio of the thickness of the solder gradient layer 100 to the area of orthogonal projection of the solder gradient layer 100 on the light-emitting element 20 is in a range of 0.001 to 0.1, that is, h1/S1=0.001˜0.1. In some specific embodiments, the h1/S1 is preferably in a range of 0.002 to 0.028. More specifically, for example, the h1/S1 is 0.0037 when the light-emitting element 20 corresponds to a LED chip of model 3458, the h1/S1 is 0.028 when the light-emitting element 20 corresponds to the LED chip of model 1525, or the h1/S1 is 0.0192 when the light-emitting element 20 corresponds to the LED chip of model 1730. By setting the ratio of the thickness to the area of the solder gradient layer 100 to the above ratio, the soldering is more stable, the electrical connectivity between the light-emitting device 2 and the backplate 300 is better, and the resistance is lower when the light-emitting device 2 is soldered to the backplate 300.

In some embodiments, a shape of orthographic projection of the solder gradient layer 100 on the light-emitting element 20 is rectangular, and lengths of two perpendicular sides of the rectangle are denoted as W1 and W2, respectively. The area S1 of orthographic projection of the solder gradient layer 100 on the light-emitting element 20 is equal to a product of W1 and W2. For example, the thickness of the solder gradient layer 100 can be determined with reference to the side length W1 when W1 is greater than W2. For example, a ratio of the thickness h1 of the solder gradient layer 100 to the side length W1 is in a range of 0.01 to 0.3. Of course, the shape of orthographic projection of the solder gradient layer 100 on the light-emitting element 20 can be another shape, such as a circle, an ellipse, an irregular shape, etc., and the thickness of the solder gradient layer 100 can be determined with reference to the maximum width Wmax of orthographic projection of the solder gradient layer 100 on the light-emitting element 20, and a ratio of the thickness h1 of the solder gradient layer 100 to the maximum width Wmax of orthographic projection of the solder gradient layer 100 on the light-emitting element 20 is in a range of 0.01 to 0.3. In some specific embodiments, the h1/Wmax is preferably in a range of 0.06 to 0.2. More specifically, for example, the h1/Wmax is 0.067 when the light-emitting element 20 corresponds to the LED chip of model 3458, the h1/Wmax is 0.18 when the light-emitting element 20 corresponds to the LED chip of model 1525, or the h1/Wmax is 0.15 when the light-emitting element 20 corresponds to the LED chip of model 1730. By setting the ratio of the thickness of the solder gradient layer 100 to the maximum width to the above ratio, the soldering is more stable, the electrical connectivity between the light-emitting device 2 and the backplate 300 is better, and the resistance value is lower when the light-emitting device 2 is soldered to the backplate 300. In some embodiments, an area of orthographic projection of the first adhesive layer 201 on the light-emitting epitaxial layer 203 is denoted as S2, and an area of orthographic projection of the solder gradient layer 100 on the light-emitting epitaxial layer 203 is denoted as S3. Combining with FIGS. 2A and 2B, the area S2 can also be understood as an area of orthographic projection of the first adhesive layer 201 on the LED chip substrate 200, and the area S3 can also be understood as an area of orthographic projection of the solder gradient layer 100 on the LED chip substrate 200. In some embodiments, the area S2 is different from the area S3. Specifically, referring to FIG. 2C, the area S2 is larger than the area S3, and more specifically, the area S2 is 1.15 to 2.5 times of the area S3. That is, in some embodiments, the area of orthographic projection of the first adhesive layer 201 on the light-emitting epitaxial layer 203 is 1.15 to 2.5 times of the area of orthographic projection of the solder gradient layer 100 on the light-emitting epitaxial layer 203, which can prevent the solder gradient layer 100 from overflowing when it melts, provide a larger soldering area, and play a better soldering aid effect. Referring to FIG. 2D, in some embodiments, the first adhesive layer 201 extends to sides of the solder gradient layer 100 towards a side close to the solder gradient layer 100, it can be understood that a groove structure is formed by the first adhesive layer 201, and the solder gradient layer 100 is disposed in the groove structure to better prevent the overflow of the solder gradient layer 100.

In some embodiments, an area of orthographic projection of the electrode structure 204 on the light-emitting epitaxial layer 203 is denoted as S4, which can also be understood as an area of orthographic projection of the electrode structure 204 on the LED chip substrate 200 in combination with FIGS. 2A and 2B. In some embodiments, the area S4 is different from the area S2. Referring to FIG. 2F, the area S2 is larger than the area S4, and more specifically, the area S2 is 1.15-2.5 times of the area S4, that is, the area of orthographic projection of the first adhesive layer 201 on the light-emitting epitaxial layer 203 is 1.15-2.5 times of the area of orthographic projection of the electrode structure 204 on the light-emitting epitaxial layer 203. The electrode structure 204 can be effectively isolated from the solder gradient layer 100 by the first adhesive layer 201. As shown in FIG. 2F, the area S2 can be set to be larger than the area S3 and larger than the area S4 at the same time, but the embodiment does not limit a size relationship between the areas S3 and S4.

The light-emitting device 2 is used for soldering, and a method for the soldering includes the following steps.

S101: a light-emitting device 2 is provided.

Referring to FIG. 1A to FIG. 2F or FIG. 5, the light-emitting device 2 is provided, which can be the light-emitting device 2 mentioned in the above embodiment, and the light-emitting device 2 includes the light-emitting element 20 and the solder gradient layer 100, the light-emitting element 20 is a LED chip, and a structure of the LED chip is the same as that of the above LED chip, so the details are not repeated here. The solder gradient layer 100 is disposed on the pad layer 202 of the light-emitting element 20, and the melting point of the solder gradient layer 100 gradually decreases in the direction facing away from the pad layer 202. The structure of the solder gradient layer 100 can be any solder gradient layer 100 in the above embodiment, so the details are not repeated here. In the embodiment, the light-emitting device 2 shown in FIG. 1A will be described as an example.

S102: a backplate is provided.

Referring to FIG. 5, the backplate 300 is provided. A surface of the backplate 300 is provided with a pad for soldering the light-emitting device 2. The pad includes a primary soldering pad 302 for soldering the light-emitting device 2 and a repair pad (not shown in the figure) for soldering the light-emitting element for repairing. The repair pad is arranged in one-to-one correspondence with the primary soldering pad 302.

Optionally, a second adhesive layer 301 is provided between the primary soldering pad 302 and the backplate 300 to fix the primary soldering pad 302 and an electrode layer on the backplate 300.

S103: the light-emitting device is transferred to the primary soldering pad, and the solder gradient layer is heated at a first soldering temperature to solder the light-emitting device to the primary soldering pad.

Referring to FIG. 5, the chip (i.e., the light-emitting device 2) is transferred to the primary soldering pad 302, and the solder gradient layer 100 on the light-emitting device 2 is melted at the first soldering temperature, so that the chip (i.e., the light-emitting device 2) is soldered to the primary soldering pad 302 of the backplate 300, and the primary soldering is completed. In the embodiment, the first soldering temperature is controlled in a range of 120° C. to 230° C. For example, the first soldering temperature may be 150° C., 180° C. or 200° C.

S104: the light-emitting device is transferred to the repair pad corresponding to the light-emitting device that cannot be normally lit, and the solder gradient layer is heated at a second soldering temperature to solder the light-emitting device to the repair pad.

Referring to FIG. 5 or 6, the primary soldered chip is detected, when it is found that the chip cannot be normally lit, the solder gradient layer 100 on the chip can be heated at the second soldering temperature to solder the chip (that is, the light-emitting device 2) to the repair pad. In this process, it is necessary to control the first soldering temperature and the second soldering temperature within the melting point range of the solder gradient layer 100. And during the soldering, the second soldering temperature is controlled to be less than the first soldering temperature, so as to prevent the second soldering temperature from affecting solder joints formed during the primary soldering, and thus affect the reliability of the solder joints. In the embodiment, the second soldering temperature is in a range of 120° C. to 180° C. For example, the second soldering temperature may be 120° C., 150° C. or 180° C.

In the light-emitting device 2 of the embodiment, the solder gradient layer 100 is formed on the pad layer 202, in the process of soldering the light-emitting device 2 to the backplate 300, because the solder gradient layer 100 includes multiple melting point regions or metal layers with different melting points, the temperature of the primary soldering is controlled to be higher than that of the repair soldering in the processes of primary soldering and repair soldering, which can avoid an influence of the repair soldering on the solder joints formed during the primary soldering and effectively control the yield of soldering.

### Embodiment 2

The embodiment provides a backplate assembly 3 for soldering a light-emitting element. The backplate assembly 3 includes a backplate 300 and a solder gradient layer 100 disposed on a pad of the backplate 300. The solder gradient layer 100 is disposed on the pad of the backplate 300, and a melting point of the solder gradient layer 100 gradually decreases in a direction facing away from the pad.

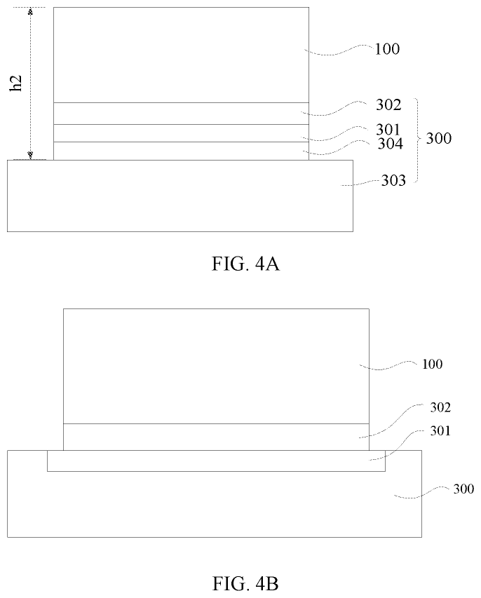

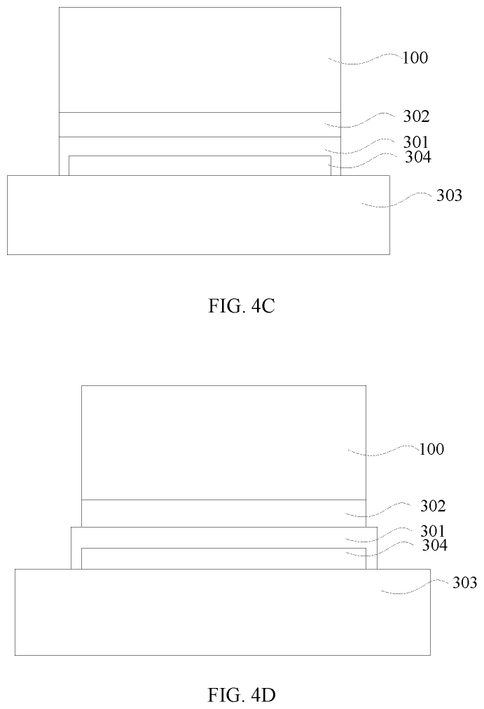

Referring to FIG. 3A or 3B, the backplate 300 (which is combined with the solder gradient layer 100 to form the backplate assembly 3) is used to carry the light-emitting element to form a display panel. Specifically, the backplate 300 includes a substrate 303 (please refer to FIG. 4C or 4D) and a driving circuit layer (not shown in figure) disposed on the substrate 303. Optionally, the driving circuit layer includes a thin-film transistor and an electrode electrically connected to the thin-film transistor, which are sequentially arranged on the substrate 303. The thin-film transistor includes an active layer, a gate insulation layer, a gate electrode, a source electrode and a drain electrode, etc. Optionally, the thin-film transistor can be a low temperature poly-silicon (LTPS) thin-film transistor or indium gallium zinc oxide (IGZO) thin-film transistor.

A surface of an electrode layer of the backplate 300 is provided with a primary soldering pad 302, and the solder gradient layer 100 is formed on a surface of the primary soldering pad 302. Referring to FIG. 4C or 4D, in some embodiments, the electrode layer of the backplate 300 includes a connecting electrode 304 disposed on the substrate 303, and the connecting electrode 304 is disposed on a side of the pad (e.g., the primary soldering pad 302) facing away from the solder gradient layer 100, that is, the connecting electrode 304 is disposed between the substrate 303 and the primary soldering pad 302. In some embodiments, the number of the connecting electrode 304 is multiple, for example, two connecting electrodes 304 corresponding to a soldering position of the light-emitting element are provided for soldering two electrodes of the light-emitting element respectively. For a vertical LED chip, one position of the LED chip can only correspond to one connecting electrode 304, the number of the primary soldering pad 302 corresponds to the number of the connecting electrode 304, and each connecting electrode 304 is provided with one primary soldering pad 302.

In an embodiment, referring to FIG. 3A, the solder gradient layer 100 includes a single-layer structure formed of at least two metal materials, and a content of each metal material in the single-layer structure is different in the direction facing away from the primary soldering pad 302. Specifically, in this embodiment, the solder gradient layer 100 includes tin and indium. The solder gradient layer 100 includes a first melting point region 110, a second melting point region 120 and a third melting point region 130 sequentially arranged in the direction facing away from the primary soldering pad 302. A melting point of the first melting point region 110 is in a range of 180° C. to 230° C., a melting point of the second melting point region 120 is in a range of 120° C. to 180° C. and a melting point of the third melting point region 130 is in a range of 100° C. to 120° C. In some embodiments, an indium content of the first melting point region 110 is in a range of 0 to 25%, an indium content of the second melting point region 120 is in a range of 25% to 60%, and an indium content of the third melting point region 130 is in a range of 60% to 70%. The solder gradient layer 100 can be gradually formed on the pad of the backplate 300 by multi-source evaporation. For example, in an evaporation process, a ratio of tin to indium is successively controlled as follows: Sn:In=8:1, Sn:In=7:1, Sn:In=6:1, Sn:In=5:1, Sn:In=4:1, Sn:In=3:1 and Sn:In=2:1. After evaporating the same thickness under the same proportion of indium and tin, the proportion of indium and tin is adjusted once until the solder gradient layer 100 is formed.

In another embodiment, referring to FIG. 3B, the solder gradient layer 100 includes a multi-layer structure, and the multi-layer structure includes multiple metal layers which are sequentially stacked, and the multiple metal layers have different melting points. Each metal layer can be formed by mixing at least two metals or a single metal, and the metals contained in each metal layer can be the same or different. It should be noted that in this embodiment, as long as melting points of the metal layers are different and the melting points of the metal layers gradually decrease in the direction facing away from the primary soldering pad 302, the material composition of each metal layer is not limited. Specifically, referring to FIG. 3B, the solder gradient layer 100 includes a first metal layer 101, a second metal layer 102 and a third metal layer 103 sequentially arranged in the direction facing away from the primary soldering pad 302, and each metal layer is formed by multi-source evaporation. A melting point of the first metal layer 101 is in a range of 180° C. to 230° C., a melting point of the second metal layer 102 is in a range of 120° C. to 180° C., and a melting point of the third metal layer 103 is in a range of 100° C. to 120° C. The first metal layer 101 can be made of tin, the second metal layer 102 can be made of indium, and the third metal layer 103 can be made of indium and tin.

Referring to FIG. 4A, a distance h2 between a surface of the solder gradient layer 100 facing away from the pad and a surface of the connecting electrode 304 facing away from the pad (e.g., the primary soldering pad 302) is defined as a thickness of the solder gradient layer 100, and an area of orthographic projection of the solder gradient layer 100 on the backplate 300 can be denoted as A1, which can also be understood as an area of orthographic projection of the solder gradient layer 100 on the substrate 303. In some embodiments, a ratio of the thickness h2 to the area A1 of the solder gradient layer 100 is in a range from 0.001 to 0.1, that is, h2/A1=0.001˜0.1. In some specific embodiments, the h2/A1 is preferably in a range of 0.002 to 0.028. More specifically, for example, the h2/A1 is 0.0037 in the backplate assembly 3 used for soldering the LED chip with model 3458, the h2/A1 is 0.028 in the backplate assembly 3 used for soldering the LED chip with model 1525, or the h2/A1 is 0.0192 in the backplate assembly 3 used for soldering the LED chip with model 1730. By setting the ratio of the thickness to the area of the solder gradient layer 100 to the above ratio, the soldering between the light-emitting element and the backplate 300 can be secure.

In some embodiments, a shape of orthographic projection of the solder gradient layer 100 on the backplate 300 is rectangular, and lengths of two perpendicular sides of the rectangle are L1 and L2, respectively. The area A1 of orthographic projection of the solder gradient layer 100 on the backplate 300 is equal to a product of L1 and L2. For example, the thickness of the solder gradient layer 100 can be determined with reference to the side length L1 when L1 is greater than L2. For example, a ratio of the thickness h2 of the solder gradient layer 100 to the side length L1 is in a range from 0.01 to 0.3. Of course, the shape of orthographic projection of the solder gradient layer 100 on the backplate 300 can also be another shape, such as a circle, an ellipse, an irregular shape, etc., so the thickness of the solder gradient layer 100 can be set with reference to the maximum width Lmax of orthographic projection of the solder gradient layer 100 on the backplate 300, and a ratio of the thickness h2 of the solder gradient layer 100 to the maximum width Lmax of orthographic projection of the solder gradient layer 100 on the backplate 300 is in a range from 0.01 to 0.3. In some specific embodiments, the h2/Lmax is preferably in a range of 0.06 to 0.2. More specifically, for example, the h2/Lmax is 0.067 in the backplate assembly 3 for soldering the LED chip of model 3458, the h2/Lmax is 0.18 in the backplate assembly 3 for soldering the LED chip of model 1525, or the h2/Lmax is 0.15 in the backplate assembly 3 for soldering the LED chip of model 1730.

In some embodiments, an adhesive layer is provided between the connecting electrode 304 and the pad. In this embodiment, the adhesive layer on the backplate 300 is a second adhesive layer 301, and an area of orthographic projection of the second adhesive layer 301 on the substrate 303 is denoted as A2, and an area of orthographic projection of the solder gradient layer 100 on the substrate 303 is denoted as A3. In some embodiments, the area A2 is different from the area A3. Specifically, referring to FIG. 4B, the area A2 is larger than the area A3, and more specifically, the area A2 is 1.15 to 2.5 times of the area A3. That is, in some embodiments, the area of orthographic projection of the second adhesive layer 301 on the substrate 303 is 1.15 to 2.5 times of that of the solder gradient layer 100 on the substrate 303, which can prevent the solder gradient layer 100 from overflowing when it melts, provide a larger soldering area, and play a better soldering aid effect. In some embodiments, the second adhesive layer 301 further extends to sides of the solder gradient layer 100 towards a side close to the solder gradient layer 100, it can be understood that a groove structure formed by the second adhesive layer 301, and the solder gradient layer 100 is disposed in the groove structure to better prevent the overflow of the solder gradient layer 100.

In some embodiments, an area of orthogonal projection of the connecting electrode 304 on the substrate 303 is denoted as A4. In some embodiments, the area A4 is different from the area A2. Referring to FIG. 4D, the specific area A2 is larger than the area A4, and more specifically, the area A2 is 1.15-2.5 times of the area A4, that is, the area of orthographic projection of the second adhesive layer 301 on the substrate 303 is 1.15-2.5 times of the area of orthographic projection of the connecting electrode 304 on the substrate 303, and the connecting electrode 304 can be effectively isolated from the solder gradient layer 100 by the second adhesive layer 301. As shown in FIG. 4D, the second adhesive layer 301 further extends to sides of the connecting electrode 304 towards a side close to the connecting electrode 304 to achieve better isolation effect.

The light-emitting element is soldered on the backplate assembly 3, and a soldering method specifically includes the following steps.

S101: a backplate assembly is provided.

Referring to FIG. 3A to FIG. 4D or FIG. 7, the backplate 300 is provided. The structure of the backplate 300 is the same as that of the aforementioned backplate 300. A pad of the backplate 300 is provided with a solder gradient layer 100 which is combined with the backplate 300 to form the backplate assembly 3. A melting point of the solder gradient layer 100 gradually decreases in the direction facing away from the pad. The specific setting of the solder gradient layer 100 can be referred to the previous description of the embodiment 2, and will not be repeated here. In this embodiment, the backplate assembly 3 shown in FIG. 3B will be described as an example.

S102: a light-emitting element is provided.

The light-emitting element is provided, which can be a LED chip, and the LED chip includes a LED chip substrate 200 and a light-emitting structure (not shown in the figure) formed on a surface of the LED chip substrate 200. Optionally, the light-emitting structure includes a first semiconductor layer, an active layer and a second semiconductor layer with the opposite conductivity type to the first semiconductor layer, which are sequentially formed on the surface of the LED chip substrate 200, and the active layer is a light-emitting layer of the light-emitting element. The first semiconductor layer may be an N-type semiconductor layer and the second semiconductor layer may be a P-type semiconductor layer. Of course, it is possible that the first semiconductor layer is a P-type semiconductor layer and the second semiconductor layer is an N-type semiconductor layer. Alternatively, the first semiconductor layer may be an N-type GaN layer, the active layer may be a quantum well layer, and the second semiconductor layer may be a P-type GaN layer.

In this embodiment, an electrode structure (not shown in the figure) is formed on another surface of the LED chip substrate 200, and a pad layer is formed on a surface of the electrode structure, which is used for soldering the LED chip to the backplate 300.

S103: the solder gradient layer is melted at a first soldering temperature to solder the light-emitting element to the backplate.

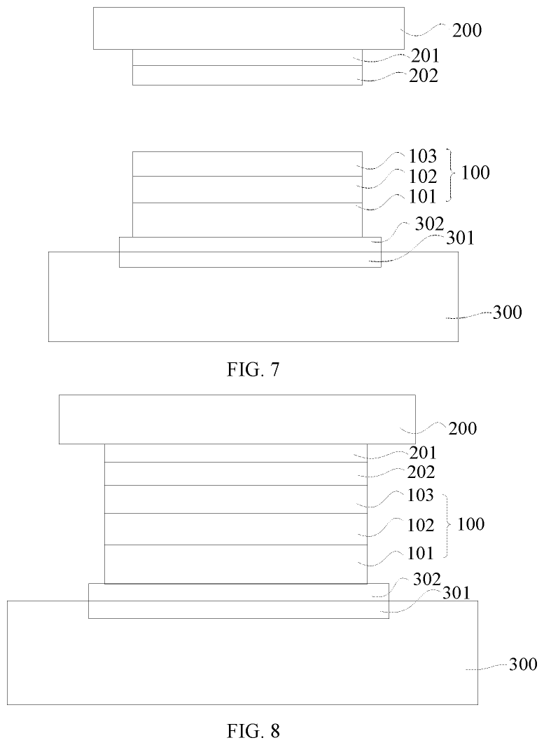

Referring to FIG. 7 or 8, the solder gradient layer 100 on the backplate 300 is melted at the first soldering temperature to solder the chip (i.e., the light-emitting element) to the backplate 300, so as to complete the primary soldering. It should be noted that during the primary soldering, it is necessary to control the first soldering temperature as small as possible, so as to melt a solder with a smaller melting point located at an end of the solder gradient layer 100 facing away from the backplate 300, and the solder in other areas is not melted. Optionally, the first soldering temperature is in a range of 120° C. and 180° C., and the first soldering temperature can be 120° C., 150° C. and 180° C.

S104: lighting detection is performed on the light-emitting element soldered to the backplate, and the light-emitting element is directly removed when the light-emitting element cannot be normally lit.

Referring to FIG. 8, after the primary soldering, the lighting detection is performed on the chip (i.e., the light-emitting element) soldered to the backplate 300, and the chip is directly removed when the light-emitting element cannot be normally lit.

In the embodiment, in the process of soldering the light-emitting element to the backplate assembly 3, because the solder gradient layer in the backplate assembly 3 includes multiple melting point regions or metal layers with different melting points, the solder with the relatively low melting point facing away from the backplate 300 is melted at the lower soldering temperature during the primary soldering, and most of the solder with the relatively high melting point close to the backplate 300 is not melted. The light-emitting element is detected, when the defective light-emitting element is found, the chip after the primary soldering can be easily removed, which improves the repair efficiency of LED chips.

### Embodiment 3

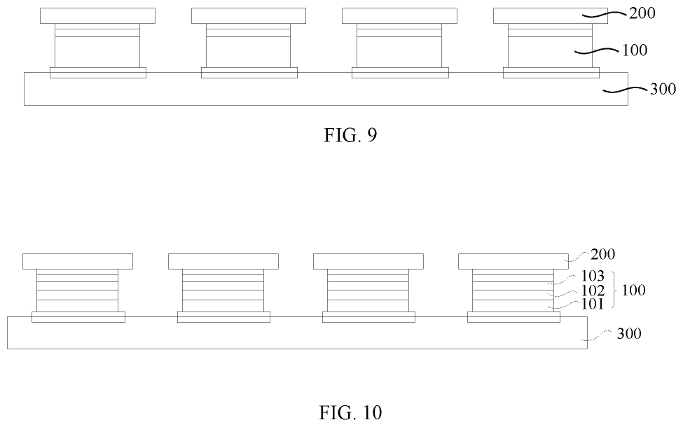

The embodiment provides a display panel, referring to FIG. 9, the display panel includes a backplate 300 and light-emitting devices fixed on the backplate 300. Each light-emitting device is the light-emitting device 2 described in the embodiment 1. In the embodiment, the light-emitting element in each light-emitting device 2 is a LED chip, and each light-emitting device 2 is soldered to the backplate 300 through the solder gradient layer 100 on the pad layer 202.

In the display panel of the embodiment, in the process of soldering the light-emitting device 2 to the backplate 300, because the solder gradient layer 100 in the light-emitting device 2 includes multiple melting point regions or metal layers with different melting points, a temperature of primary soldering is controlled to be higher than that of repair soldering in the processes of primary soldering and repair soldering, which can avoid an influence of the repair soldering on solder joints formed during the primary soldering, effectively control the quality and yield of soldering, and further improve the yield and service life of the display panel.

### Embodiment 4

The embodiment provides a display panel, referring to FIG. 10, the display panel includes a backplate 300 and light-emitting elements fixed on the backplate 300. The backplate 300 is the backplate 300 described in the embodiment 2, and the solder gradient layer 100 is disposed on the pad of the backplate 300 to form the backplate assembly 3 described in the embodiment 2, and the melting point of the solder gradient layer 100 gradually decreases in the direction facing away from the pad. For the specific setting of the solder gradient layer 100, please refer to the description of the aforementioned embodiment 2, which will not be repeated here. Each light-emitting element is soldered to the backplate 300 through the solder gradient layer 100 located on the pad of the backplate 300. In the embodiment, each light-emitting element is a LED chip.

In the display panel of the embodiment, in the process of soldering the light-emitting element to the backplate assembly 3 of the embodiment 2, because the solder gradient layer in the backplate assembly 3 includes multiple melting point regions or metal layers with different melting points, the solder with the relatively low melting point facing away from the backplate 300 is melted at the lower soldering temperature during the primary soldering, and most of the solder with the relatively high melting point close to the backplate 300 is not melted. The light-emitting elements are detected, when a defective light-emitting element is found, this primary soldered chip can be easily removed, thus improving the repair efficiency of LED chips.

The above embodiments are merely illustrative of the principle and efficacy of the disclosure, and are not intended to limit the disclosure. Any person skilled in the art can modify or change the above embodiments without departing from the spirit and scope of the disclosure. Accordingly, all equivalent modifications and changes made by those skilled in the art without departing from the spirit and scope of the disclosure are covered by scope of protection of the appended claims.

What is claimed is:

1. A light-emitting device, comprising:
a light-emitting element, comprising: a light-emitting epitaxial layer and a pad layer formed on the light-emitting epitaxial layer; and
a solder gradient layer, disposed on the pad layer of the light-emitting element; wherein a melting point of the solder gradient layer gradually decreases in a direction facing away from the pad layer.

2. The light-emitting device as claimed in claim 1, wherein the solder gradient layer is a single-layer structure comprising at least two metal materials, and a content of each of the at least two metal materials in the single-layer structure is different in the direction facing away from the pad layer.

3. The light-emitting device as claimed in claim 2, wherein the solder gradient layer comprises indium (In) and tin (Xi), and a content of the indium in the solder gradient layer gradually increases in the direction facing away from the solder pad layer.

4. The light-emitting device as claimed in claim 3, wherein the solder gradient layer comprises a first melting point region, a second melting point region and a third melting point region sequentially arranged in the direction facing away from the pad layer; and a melting point of the first melting point region is in a range of 180° C. to 230° C., a melting point of the second melting point region is in a range of 120° C. to 180° C., and a melting point of the third melting point region is in a range of 100° C. to 120° C.

5. The light-emitting device as claimed in claim 4, wherein a content of the indium in the first melting point region is in a range of 0 to 25%, a content of the indium in the second melting point region is in a range of 25% to 60%, and a content of the indium in the third melting point region is in a range of 60% to 70%.

6. The light-emitting device as claimed in claim 1, wherein the light-emitting element further comprises an electrode structure disposed between the light-emitting epitaxial layer and the pad layer; a distance between a surface of the solder gradient layer facing away from the light-emitting element and a surface of the electrode structure facing away from the solder layer is defined as a thickness of the solder gradient layer; a ratio of the thickness of the solder gradient layer to an area of orthogonal projection of the solder gradient layer on the light-emitting element is in a range of 0.001 to 0.1.

7. The light-emitting device as claimed in claim 1, wherein the light-emitting element further comprises an electrode structure disposed between the light-emitting epitaxial layer and the pad layer; a distance between a surface of the solder gradient layer facing away from the light-emitting element and a surface of the electrode structure facing away from the solder layer is defined as a thickness of the solder gradient layer; and a ratio of the thickness of the solder gradient layer to a maximum width of orthogonal projection of the solder gradient layer on the light-emitting element is in a range of 0.01 to 0.3.

8. The light-emitting device as claimed in claim 1, wherein the light-emitting element further comprises an adhesive layer disposed between the light-emitting epitaxial layer and the pad layer, and an area of orthogonal projection of the adhesive layer on the light-emitting epitaxial layer is 1.15 to 2.5 times of an area of orthographic projection of the solder gradient layer on the light-emitting epitaxial layer.

9. The light-emitting device as claimed in claim 1, wherein the light-emitting element further comprises an adhesive layer disposed between the light-emitting epitaxial layer and the pad layer, and an electrode structure disposed between the adhesive layer and the light-emitting epitaxial layer, and an area of orthographic projection of the adhesive layer on the light-emitting epitaxial layer is 1.15 to 2.5 times of an area of orthographic projection of the electrode structure on the light-emitting epitaxial layer.

10. A backplate assembly, comprising:
a backplate, comprising a pad for soldering a light-emitting element; and
a solder gradient layer, disposed on the pad of the backplate; wherein a melting point of the solder gradient layer gradually decreases in a direction facing away from the pad.

11. The backplate assembly as claimed in claim 10, wherein the solder gradient layer is a single-layer structure comprising at least two metal materials, and a content of each of the at least two metal materials in the single-layer structure is different in the direction facing away from the pad.

12. The backplate assembly as claimed in claim 11, wherein the solder gradient layer comprises indium and tin, and a content of the indium in the solder gradient layer gradually increases in the direction facing away from the pad.

13. The backplate assembly as claimed in claim 12, wherein the solder gradient layer comprises a first melting point region, a second melting point region and a third melting point region sequentially arranged in the direction facing away from the pad; and a melting point of the first melting point region is in a range of 180° C. to 230° C., a melting point of the second melting point region is in a range of 120° C. to 180° C., and a melting point of the third melting point region is in a range of 100° C. to 120° C.

14. The backplate assembly as claimed in claim 13, wherein a content of the indium in the first melting point region is in a range of 0 to 25%, a content of the indium in the second melting point region is in a range of 25% to 60%, and a content of the indium in the third melting point region is in a range of 60% to 70%.

15. The backplate assembly as claimed in claim 10, wherein the backplate further comprises a connecting electrode disposed on a side of the pad facing away from the solder gradient layer; a distance between a surface of the solder gradient layer facing away from the pad and a surface of the connecting electrode facing away from the pad is defined as a thickness of the solder gradient layer; and a ratio of the thickness of the solder gradient layer to an area of orthogonal projection of the solder gradient layer on the backplate is in a range of 0.001 to 0.1.

16. The backplate assembly as claimed in claim 10, wherein the backplate further comprises a connecting electrode disposed on a side of the pad facing away from the solder gradient layer; a distance between a surface of the solder gradient layer facing away from the pad and a surface of the connecting electrode facing away from the pad is defined as a thickness of the solder gradient layer; and a ratio of the thickness of the solder gradient layer to a maximum width of orthogonal projection of the solder gradient layer on the backplate is in a range of 0.01 to 0.3.

17. The backplate assembly as claimed in claim 10, wherein the backplate further comprises a substrate, the pad is disposed on a surface of the substrate, and the backplate further comprises an adhesive layer disposed between the pad and the substrate; and an area of orthographic projection of the adhesive layer on the substrate is 1.15 to 2.5 times of an area of orthographic projection of the solder gradient layer on the substrate.

18. The backplate assembly as claimed in claim 10, wherein the backplate further comprises a substrate and a connecting electrode disposed on the substrate, and the pad is disposed on the connecting electrode; the backplate further comprises an adhesive layer disposed between the pad and the connecting electrode, and an area of orthographic projection of the adhesive layer on the substrate is 1.15 to 2.5 times of an area of orthographic projection of the connecting electrode on the substrate.

19. A display panel comprising:
a backplate; and
a light-emitting device, fixed on the backplate; wherein the light-emitting device is the light-emitting device as claimed in claim 1, and the light-emitting device is soldered on the backplate through the solder gradient layer on the pad layer.

20. A display panel comprising:
the backplate assembly as claimed in claim 10; and
a light-emitting element, soldered on the backplate assembly through the solder gradient layer.
